(19) United States
(12) Patent Application Publication
(10) Pub. No.: US 2024/0384170 A1
(43) Pub. Date: Nov. 21, 2024

(54) ETCHING SOLUTION, ETCHING METHOD, AND METHOD FOR MANUFACTURING SEMICONDUCTOR DEVICE

(71) Applicant: TOKYO OHKA KOGYO CO., LTD., Kawasaki-shi (JP)

(72) Inventors: Choitsu Go, Kawasaki-shi (JP); Kazuya Tajima, Kawasaki-shi (JP); Mai Sugawara, Kawasaki-shi (JP)

(21) Appl. No.: 18/659,906

(22) Filed: May 9, 2024

(30) Foreign Application Priority Data
May 15, 2023 (JP) 2023-080322

(51) Int. Cl. C09K 13/08; H01L 21/306

(52) U.S. Cl. CPC C09K 13/08; H01L 21/30604

(57) ABSTRACT

An etching solution having excellent etching selectivity, an etching method using the etching solution, and a method for manufacturing a semiconductor device using the etching solution. The etching solution includes an oxidizing agent, a fluoride, a compound represented by the following formula (1), a carboxylic acid as a solvent, and water,

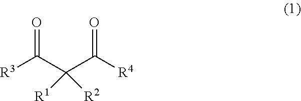

and R¹ and R² each independently represents a hydrogen atom, a halogen atom, an alkyl group, a fluoroalkyl group, or an alkoxy group, and R³ and R⁴ each independently represents a halogen atom, a hydroxy group, an alkyl group, a fluoroalkyl group, or an alkoxy group.

This application claims priority to Japanese Patent Application No. 2023-080322, filed May 15, 2023, the entire content of which is incorporated herein by reference.

### BACKGROUND OF THE INVENTION

### Field of the Invention

The present invention relates to an etching solution, an etching method, and a method for manufacturing a semiconductor device.

### Related Art

In the related art, scaling a configuration in an integrated circuit can increase a density of functional units on a semiconductor chip. For example, reducing a size of a transistor enables a larger number of memory elements to be incorporated into a chip, leading to manufacture of products with increased capacity.

In manufacturing a field-effect transistor (FET) for an integrated circuit device, Ge is used as a semiconductor crystal material other than silicon. Ge has characteristics that are advantageous over silicon in some cases, such as high charge carrier (hole) mobility, bandgap offset, different lattice constants, and an ability to alloy with silicon to form a semiconducting binary alloy of SiGe.

The Ge material is used in various semiconductor devices, such as a gate-all-around transistor (GAA FET). The gate-all-around transistor has a structure in which a channel such as a nano-sheet or a nanowire is covered with a gate, and can improve performance and promote miniaturization of the transistor. When manufacturing the gate-all-around transistor, at least a part of silicon germanium is removed by selectively etching the silicon germanium from a structure obtained by alternately stacking silicon and silicon germanium. As an etching solution used in such etching, there is disclosed an etching composition which selectively dissolves silicon germanium over silicon and which contains an oxidizing agent (A) and an organic acid (B) and, the oxidizing agent (A) containing nitric acid, and a content of the organic acid (B) being 50 mass % or more in 100 mass % of the etching composition (see Patent Document 1).

Patent Document 1: Japanese Unexamined Patent Application, Publication No. 2022-94679

### SUMMARY OF THE INVENTION

When manufacturing the gate-all-around transistor, at least a part of silicon germanium having a higher concentration of germanium is removed by selectively etching silicon germanium having a higher concentration of germanium from a structure obtained by alternately stacking silicon germanium and silicon germanium having a higher concentration of germanium than that of silicon germanium.

However, when the etching solution in the related art as described in Patent Document 1 is used to etch silicon germanium and silicon germanium having a higher concentration of germanium than that of silicon germanium, there is a problem that etching selectivity, compared to silicon germanium, towards silicon germanium having a higher concentration of germanium than that of silicon germanium is insufficient. Therefore, an etching solution having excellent etching selectivity, compared to silicon germanium, towards silicon germanium having a higher concentration of germanium than that of silicon germanium is desired. The above-described problem of the etching selectivity is not limited to the etching of silicon germanium having a higher concentration of germanium in manufacturing a gate-all-around transistor, but also exists in etching of a compound represented by Si₁₋ₓGeₓ (x is 0.25 or more and 1 or less) in manufacturing various semiconductor devices.

The present invention has been made in view of the above circumstances, and a problem of the present invention is to provide an etching solution having excellent etching selectivity, compared to silicon germanium, towards a compound represented by Si₁₋ₓGeₓ (x is 0.25 or more and 1 or less) having a higher concentration of germanium than that of silicon germanium, an etching method using the etching solution, and a method for manufacturing a semiconductor device using the etching solution.

The present inventors have found that the above-described problem can be resolved by an etching solution containing an oxidizing agent, a fluoride, a compound represented by the following formula (1), carboxylic acid as a solvent, and water, and have completed the present invention. Specifically, the present invention provides the following.

1 An etching solution, containing: an oxidizing agent; a fluoride; a compound represented by the following formula (1); a carboxylic acid as a solvent; and water.

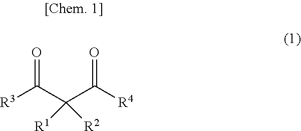

wherein R¹ and R² each independently represent a hydrogen atom, a halogen atom, an alkyl group, a fluoroalkyl group, or an alkoxy group, and R³ and R⁴ each independently represent a halogen atom, a hydroxy group, an alkyl group, a fluoroalkyl group, or an alkoxy group.

2 The etching solution as described in aspect [1], in which a ratio ((mass of compound represented by formula (1))/(mass of carboxylic acid as solvent)) of a mass of the compound represented by the formula (1) to a mass of the carboxylic acid as a solvent is 0.10 or more and 0.25 or less.

3 The etching solution as described in aspect [1] or [2], in which a mass of the compound represented by the formula (1) is 8.5 mass % or more and 20% or less with respect to a mass of the etching solution, and a mass of the carboxylic acid as a solvent is 70 mass % or more and 98 mass % or less with respect to the mass of the etching solution.

4 The etching solution as described in any one of aspects [1] to [3], in which the oxidizing agent contains at least one of nitric acid or hydrogen peroxide.

5 The etching solution as described in any one of aspects [1] to [4], in which the fluoride contains at least one of hexafluorosilicic acid or hydrogen fluoride.

6 The etching solution as described in any one of aspects [1] to [5], in which the etching solution etches a compound represented by Si₁₋ₓGeₓ (x is 0.25 or more and 1 or less).

7 An etching method for etching an object comprising a compound represented by Si₁₋ₓGeₓ (x is 0.25 or more and 1 or less), the etching method including:

an etching step of etching the compound represented by Si₁₋ₓGeₓ by bringing the etching solution as described in any one of aspects [1] to [6] into contact with the compound represented by Si₁₋ₓGeₓ.

8 The etching method as described in aspect [7], in which the object is a substrate including a first SiGe region made of the compound represented by Si₁₋ₓGeₓ and a second SiGe region made of a compound represented by Si_{1-y}Ge_{y} (y is a value of 0 or more and less than x).

9 A method for manufacturing a semiconductor device, including: an etching step of etching an object containing a compound represented by Si₁₋ₓGeₓ (x is 0.25 or more and 1 or less) by using the etching solution as described in any one of aspects [1] to [6].

10 The method for manufacturing a semiconductor device as described in aspect [9], in which the semiconductor device is a gate-all-around transistor.

The present invention can provide an etching solution having excellent etching selectivity, compared to silicon germanium, towards a compound represented by Si₁₋ₓGeₓ (x is 0.25 or more and 1 or less) having a higher concentration of germanium than that of silicon germanium, an etching method using the etching solution, and a method for manufacturing a semiconductor device using the etching solution.

### DETAILED DESCRIPTION OF THE INVENTION

### Etching Solution

An etching solution contains an oxidizing agent, a fluoride, a compound represented by the following formula (1), a carboxylic acid as a solvent, and water.

A compound represented by Si₁₋ₓGeₓ (x is 0.25 or more and 1 or less) (hereinafter, also referred to as “Si₁₋ₓGeₓ”) can be satisfactorily etched by using the etching solution. Since x is 0.25 or more and 1 or less, Si₁₋ₓGeₓ contains silicon germanium and germanium. In the etching solution, etching of silicon germanium having a lower concentration of germanium than that of Si₁₋ₓGeₓ (that is, a compound represented by Si_{1-y}Ge_{y} (y is a value of 0 or more and less than x) (hereinafter, also referred to as “Si_{1-y}Ge_{y}”) is more difficult than etching of Si₁₋ₓGeₓ. Since y is a value of 0 or more and less than x, Si_{1-y}Ge_{y} contains silicon germanium and germanium. Therefore, etching selectivity, compared to silicon germanium (Si_{1-y}Ge_{y}), towards Si₁₋ₓGeₓ having a higher concentration of germanium than that of silicon germanium (Si_{1-y}Ge_{y}) is excellent. That is, compared with silicon germanium (Si_{1-y}Ge_{y}), the etching solution preferentially etches Si₁₋ₓGeₓ having a higher concentration of germanium than that of silicon germanium (Si_{1-y}Ge_{y}). A difference (x-y) between x and y may be more than 0, and is preferably 0.10 or more, and more preferably 0.20 or more. The difference (x-y) between x and y is preferably 0.50 or less, and more preferably 0.40 or less.

An etching rate ER_{Si-high-Ge} of Si₁₋ₓGeₓ may be, for example, 5 nm/min or more, 10 nm/min or more, or 70 nm/min or more. An etching rate ER_{Si-low-Ge} of Si_{1-y}Ge_{y} may be, for example, 0.15 nm/min or less, 0.10 nm/min or less, or 0.05 nm/min or less. An etching selection ratio (ER_{Si-high-Ge}/ER_{Si-low-Ge}) of Si₁₋ₓGeₓ to Si_{1-y}Ge_{y} is, for example, preferably 100 or more, more preferably 120 or more, and even more preferably 200 or more.

The reason why the etching selectivity towards Si₁₋ₓGeₓ compared to Si_{1-y}Ge_{y} is excellent when the above-described etching solution is used is not clear, but is presumed as follows. When the above-described etching solution is brought into contact with an object containing Si₁₋ₓGeₓ, Si₁₋ₓGeₓ is oxidized by an oxidizing agent. An oxide of Si₁₋ₓGeₓ is etched by fluoride ions (F) derived from a fluoride in water. The etching due to the oxidizing agent and the fluoride can also function on Si_{1-y}Ge_{y}. However, due to an action of the compound represented by the formula (1), etching of Si_{1-y}Ge_{y} by the oxidizing agent and the fluoride is suppressed. And, due to the action of the compound represented by the formula (1), etching of Si₁₋ₓGeₓ by the oxidizing agent and the fluoride can be improved.

Since the above-described etching solution hardly damages Si_{1-y}Ge_{y}, it is possible to suppress a decrease in flatness (surface roughness) of Si_{1-y}Ge_{y} due to contact with the etching solution.

On the other hand, when the etching solution does not correspond to the above-described etching solution, for example, when the etching solution does not contain the compound represented by the formula (1) or does not contain the carboxylic acid as a solvent, the etching selectivity towards Si₁₋ₓGeₓ compared to Si_{1-y}Ge_{y} is poor.

When the etching solution does not contain the compound represented by the formula (1) or does not contain the carboxylic acid as a solvent, Si_{1-y}Ge_{y} is damaged, and thus the decrease in the flatness (surface roughness) of Si_{1-y}Ge_{y} is likely to occur due to contact with the etching solution.

Hereinafter, essential components contained in the etching solution such as the oxidizing agent, the fluoride, the compound represented by the formula (1), the carboxylic acid as a solvent, and water, and an optional component will be described.

### Oxidizing Agent

The etching solution contains the oxidizing agent. Examples of the oxidizing agent include hydrogen peroxide, FeCl₃, FeF₃, Fe(NO₃)₃, Sr(NO₃)₂, CoF₃, MnF₃, oxone (2KHSO₅·KHSO₄·K₂SO₄), iodic acid, vanadium (V) oxide, vanadium (IV, V) oxide, ammonium vanadate, ammonium peroxomonosulfate, ammonium chlorite, ammonium chlorate, ammonium iodate, ammonium nitrate, ammonium perborate, ammonium perchlorate, ammonium periodate, ammonium persulfate, ammonium hypochlorite, ammonium hypobromite, ammonium tungstate, sodium persulfate, sodium hypochlorite, sodium perborate, sodium hypobromite, potassium iodate, potassium permanganate, potassium persulfate, nitric acid, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxomonosulfate, peroxomonosulfate, ferric nitrate, urea peroxide, peracetic acid, orthoperiodic acid (H₅IO₆), metaperiodic acid (HIO₄), methyl-1,4-benzoquinone (MBQ), 1,4-benzoquinone (BQ), 1,2-benzoquinone, 2,6-dichloro-1,4-benzoquinone (DCBQ), toluquinone, 2,6-dimethyl-1,4-benzoquinone (DMBQ), chloranil, alloxan, N-methylmorpholine N-oxide, trimethylamine N-oxide. Among these, nitric acid or hydrogen peroxide is preferable as the oxidizing agent. The oxidizing agent may be used alone, or may be used in a combination of two or more kinds thereof.

A mass of the oxidizing agent in the etching solution is, for example, 0.01 mass % or more and 10 mass % or less, and preferably 0.1 mass % or more and 5 mass % or less, and more preferably 0.2 mass % or more and 3 mass % or less, with respect to a mass of the etching solution. When a content of the oxidizing agent is within the above-described range, Si₁₋ₓGeₓ is easily oxidized, and the etching rate with respect to Si₁₋ₓGeₓ is high.

### Fluoride

The etching solution contains the fluoride. Examples of the fluoride include hydrogen fluoride (HF), hexafluorosilicic acid (HFSA), hexafluorotitanic acid, hexafluorozirconic acid, tetrafluoroboric acid, tetrabutylammonium trifluoromethanesulfonate, tetraalkylammonium tetrafluoroborate (NR¹R²R³R⁴BF⁴) such as tetrabutylammonium tetrafluoroborate, tetraalkylammonium hexafluorophosphate (NR¹R²R³R⁴ PF⁶), tetraalkylammonium fluoride (NR¹¹R¹²R¹³R¹⁴F) such as tetramethylammonium fluoride (anhydride or hydrate thereof), ammonium bifluoride, ammonium fluoride, wherein NR¹¹, R¹², R¹³, and R¹⁴ may be the same or different from each other, and are selected from a group consisting of a hydrogen atom, a linear or branched alkyl group having 1 or more and 6 or less carbon atoms (for example, methyl, ethyl, propyl, butyl, pentyl, and hexyl), an alkoxy group having 1 or more and 6 or less carbon atoms (for example, hydroxyethyl and hydroxypropyl), or a substituted or unsubstituted aryl group (for example, benzyl). Among these, hydrogen fluoride or hexafluorosilicic acid is preferable as the fluoride. Hydrogen fluoride can be used for an aqueous solution (hydrofluoric acid). The fluoride may be used alone, or may be used in a combination of two or more kinds thereof. In the present specification, “fluoride” is a compound that does not correspond to the compound represented by the formula (1).

A mass of the fluoride in the etching solution is not particularly limited, but is, for example, 0.02 mass % or more and 5 mass % or less, preferably 0.03 mass % or more and 3.0 mass % or less, and more preferably 0.04 mass % or more and 2.0 mass % or less, with respect to the mass of the etching solution. When a content of the fluoride is within the above-described range, the etching rate with respect to Si₁₋ₓGeₓ is more easily improved.

A concentration of fluorine ions in the etching solution is not particularly limited, but is, for example, 0.005 mol/L to 2.50 mol/L, preferably 0.007 mol/L to 1.50 mol/L, more preferably 0.008 mol/L to 1.25 mol/L, and even more preferably 0.010 mol/L to 1.00 mol/L. When the concentration of the fluorine ions is within the range, the etching rate with respect to Si₁₋ₓGeₓ is more easily improved.

### Compound Represented by Formula (1)

The etching solution contains the compound represented by the following formula (1).

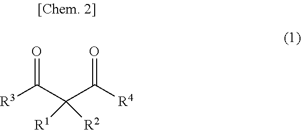

wherein R¹ and R² each independently represent a hydrogen atom, a halogen atom, an alkyl group, a fluoroalkyl group, or an alkoxy group, and R³ and R⁴ each independently represent a halogen atom, a hydroxy group, an alkyl group, a fluoroalkyl group, or an alkoxy group.

R¹ and R² may be the same or different. Examples of the halogen atom as R¹ and R² include a fluorine atom, a chlorine atom, a bromine atom, and an iodine atom. The fluorine atom is preferable from among these atoms. The alkyl group as R¹ and R² may be linear or branched, and specific examples thereof include a methyl group, an ethyl group, an n-propyl group, an isopropyl group, an n-butyl group, an isobutyl group, a sec-butyl group, and a tert-butyl group. The methyl group and the ethyl group are preferable in these groups. The fluoroalkyl group as R¹ and R² is a group in which a portion or all of hydrogen atoms of an alkyl group are substituted with a fluorine atom(s). The fluoroalkyl group as R¹ and R² may be linear or branched, and specific examples thereof include a group in which a portion or all of the hydrogen atoms of the groups exemplified as the specific examples of the alkyl group as R¹ and R² are substituted with a fluorine atom(s). The alkoxy group as R¹ and R² may be linear or branched, and specific examples thereof include a methoxy group, an ethoxy group, an n-propyloxy group, an isopropyloxy group, an n-butyloxy group, an isobutyloxy group, a sec-butyloxy group, and a tert-butyloxy group. The methoxy group and the ethoxy group are preferable in these groups. R¹ and R² are each independently and preferably a hydrogen atom or an alkyl group, and more preferably a hydrogen atom.

R³ and R⁴ may be the same or different. Examples of the halogen atom as R³ and R⁴ include a fluorine atom, a chlorine atom, a bromine atom, and an iodine atom. The fluorine atom is preferable from among these atoms. The alkyl group as R³ and R⁴ may be linear or branched, and specific examples thereof include a methyl group, an ethyl group, an n-propyl group, an isopropyl group, an n-butyl group, an isobutyl group, a sec-butyl group, and a tert-butyl group. The methyl group and the ethyl group are preferable in these groups. The fluoroalkyl group as R³ and R⁴ is a group in which a portion or all of hydrogen atoms of an alkyl group are substituted with a fluorine atom(s). The fluoroalkyl group as R³ and R⁴ may be linear or branched, and specific examples thereof include a group in which a portion or all of the hydrogen atoms of the groups exemplified as the specific examples of the alkyl group as R¹ and R² are substituted with a fluorine atom(s). The alkoxy group as R³ and R⁴ may be linear or branched, and specific examples thereof include a methoxy group, an ethoxy group, an n-propyloxy group, an isopropyloxy group, an n-butyloxy group, an isobutyloxy group, a sec-butyloxy group, and a tert-butyloxy group. The methoxy group and the ethoxy group are preferable in these groups. R³ and R⁴ are each independently and preferably a hydroxy group, an alkyl group, or a fluoroalkyl group.

Specific examples of the compound represented by the formula (1) include malonic acid, methylmalonic acid, acetylacetone, and hexafluoroacetylacetone. The compound represented by the formula (1) may be used alone, or may be used in a combination of two or more kinds thereof.

A mass of the compound represented by the formula (1) in the etching solution is not particularly limited, but is, for example, 0.01 mass % or more and 25 mass % or less, preferably 5.0 mass % or more and 20 mass % or less, and more preferably 9.0 mass % or more and 20 mass % or less, with respect to the mass of the etching solution. When a content of the compound represented by the formula (1) is within the above-described range, the etching selectivity towards S₁₋ₓGeₓ compared to Si_{1-y}Ge_{y} is more easily improved. A ratio ((mass of compound represented by formula (1))/(mass of carboxylic acid as solvent)) of the mass of the compound represented by the formula (1) to the mass of the carboxylic acid as a solvent in the etching solution is preferably 0.01 or more and 0.35 or less, more preferably 0.05 or more and 0.30 or less, and even more preferably 0.10 or more and 0.25 or less.

### Carboxylic Acid as Solvent

The etching solution contains the carboxylic acid as a solvent. The carboxylic acid as a solvent is liquid at a room temperature (25° C.) and is a compound that does not correspond to the above-described compound represented by the formula (1). Examples of the carboxylic acid as a solvent include monocarboxylic acid, and specific examples include formic acid, acetic acid, and propionic acid. The carboxylic acid as a solvent may be used alone, or may be used in a combination of two or more kinds thereof.

A mass of the carboxylic acid as a solvent in the etching solution is not particularly limited, but is, for example, 70 mass % or more and 98 mass % or less, preferably 75 mass % or more and 95 mass % or less, and more preferably 80 mass % or more and 90 mass % or less, with respect to the mass of the etching solution. When a content of the carboxylic acid as a solvent is within the above-described range, the etching rate with respect to Si₁₋ₓGeₓ is more easily improved.

### Water

The etching solution contains the water. The water functions as a solvent. The water may contain a trace component that is inevitably mixed. The water contained in the etching solution is preferably water subjected to a purification treatment, such as distilled water, ion-exchanged water, and ultrapure water (deionized water), and more preferably the ultrapure water generally used for manufacturing a semiconductor.

A mass of the water in the etching solution is not particularly limited, but is, for example, 0.5 mass % or more and 15 mass % or less, and preferably 1.0 mass % or more and 10 mass % or less, with respect to the mass of the etching solution. When a content of the water is within the above-described range, the etching rate with respect to Si₁₋ₓGeₓ is more easily improved.

### Other Components

The etching solution may further contain other components in addition to the above-described components, within a range that does not impair effects of the present invention. Examples of the other components include an organic solvent, phosphoric acid and/or derivatives thereof, a pH regulating agent, a passivation agent, and a surfactant.

### Organic Solvent

The organic solvent is not particularly limited, and examples thereof include a polar organic solvent other than the above-described carboxylic acid as a solvent.

### Polar Organic Solvent

Examples of the polar organic solvent other than the above-described carboxylic acid as a solvent include an alcohol solvent (for example, methanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol), dimethyl sulfoxide, and an ether solvent (for example, ethylene glycol dimethyl ether, diethylene glycol dimethyl ether, triethylene glycol dimethyl ether, tetraethylene glycol dimethyl ether, propylene glycol dimethyl ether).

The polar organic solvent other than the above-described carboxylic acid as a solvent may be used alone, or may be used in a combination of two or more kinds thereof.

### Phosphoric Acid and/or Derivatives Thereof

The etching solution may contain the phosphoric acid and/or derivatives thereof as a solvent, within a range that does not impair effects of the present invention. Examples of the phosphoric acid and/or derivatives thereof include a compound represented by the following formula (2).

O═P(OR)₃ (2)
wherein each R is independently a hydrogen atom or an alkyl group having 1 or more and 20 or less carbon atoms.

Wherein examples of the alkyl group having 1 or more and 20 or less carbon atoms in R include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, and isomers of the above-described alkyl group. Among them, R is preferably a hydrogen atom or an alkyl group having 1 or more and 10 or less carbon atoms, and more preferably a hydrogen atom.

The phosphoric acid and/or derivatives thereof may be used alone, or may be used in a combination of two or more kinds thereof.

### pH Regulating Agent

The pH regulating agent is preferably at least one selected from the group consisting of an acid, which does not correspond to the above components, and a salt thereof. Specifically, examples include methanesulfonic acid, trifluoromethanesulfonic acid, oxalic acid dihydrate, citric acid, tartaric acid, picolinic acid, succinic acid, lactic acid, sulfosuccinic acid, benzoic acid, pyruvic acid, maleic acid, fumaric acid, malic acid, ascorbic acid, mandelic acid, heptanoic acid, butyric acid, valeric acid, glutaric acid, phthalic acid, hypophosphorous acid, salicylic acid, 5-sulfosalicylic acid, hydrochloric acid, ethanesulfonic acid, butanesulfonic acid, p-toluenesulfonic acid, dichloroacetic acid, difluoroacetic acid, monochloroacetic acid, monofluoroacetic acid, trichloroacetic acid, trifluoroacetic acid, hydrobromic acid (62 weight %), sulfuric acid, ammonium acetate, sodium acetate, potassium acetate, tetramethylammonium acetate, other tetraalkylammonium acetates, phosphonium acetate, ammonium butyrate, ammonium trifluoroacetate, ammonium carbonate, ammonium chloride, ammonium sulfate, phosphoric acid, diammonium hydrogen phosphate, ammonium dihydrogen phosphate, bis (tetramethylammonium) hydrogen phosphate, disodium hydrogen phosphate, sodium dihydrogen phosphate, dipotassium hydrogen phosphate, potassium dihydrogen phosphate, ditetraalkylammonium hydrogen phosphate, ditetraalkylammonium dihydrogen phosphate, diphosphonium hydrogen phosphate, phosphonium dihydrogen phosphate, ammonium phosphonate, tetraalkylammonium phosphonate, sodium phosphonate, potassium phosphonate, phosphonium phosphonate, etidronic acid, and salts thereof. Among them, ammonium acetate or ammonium sulfate is preferable.

Examples of the pH regulating agent include a basic compound. As such a basic compound, a basic organic compound and a basic inorganic compound can be used. Suitable examples of the basic organic compound include quaternary ammonium salts such as organic quaternary ammonium hydroxide, alkylamines such as trimethylamine and tricthylamine, and salts of alkylamines. Examples of the basic inorganic compound include an inorganic compound containing an alkali metal or an alkaline earth metal. Examples include lithium oxide, sodium oxide, potassium oxide, rubidium oxide, and cesium oxide.

The pH regulating agent may be used alone, or may be used in a combination of two or more kinds thereof.

### Passivation Agent

The etching solution may contain the passivation agent for germanium. Examples of the passivation agent include ascorbic acid, L (+)-ascorbic acid, isoascorbic acid, ascorbic acid derivatives, boric acid, ammonium diborate, borates (for example, ammonium pentaborate, sodium tetraborate, and ammonium diborate), alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, sodium bromide, potassium bromide, rubidium bromide, magnesium bromide, calcium bromide, ammonium bromide with formula NR²¹R²²R²³R²⁴Br, wherein R²¹, R²², R²³, and R²⁴ can be the same or different from each other, and selected from the group consisting of hydrogen and a branched or linear alkyl group having 1 or more and 6 or less carbon atoms (for example, methyl, ethyl, propyl, butyl, pentyl, hexyl).

The passivation agent may be used alone, or may be used in a combination of two or more kinds thereof.

### Surfactant

The etching solution may contain a surfactant for a purpose of adjusting wettability of the etching solution with respect to the object. The surfactant can use a nonionic surfactant, an anionic surfactant, a cationic surfactant, or an amphoteric surfactant, and may use the above surfactants in combination.

Examples of the nonionic surfactant include a polyalkylene oxide alkyl phenyl ether surfactant, a polyalkylene oxide alkyl ether surfactant, a block polymer surfactant consisting of polyethylene oxide and polypropylene oxide, a polyoxyalkylene distyrenated phenyl ether surfactant, a polyalkylene tribenzyl phenyl ether surfactant, and an acetylene polyalkylene oxide surfactant.

Examples of the anionic surfactant include salts of alkylsulfonic acid, alkylbenzene sulfonic acid, alkylnaphthalene sulfonic acid, alkyldiphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkylphosphonic acid, and fatty acid. Examples of the “salt” include an ammonium salt, a sodium salt, a potassium salt, and a tetramethylammonium salt.

Examples of the cationic surfactant include a quaternary ammonium salt surfactant or an alkylpyridium surfactant.

Examples of the amphoteric surfactant include a betaine surfactant, an amino acid surfactant, an imidazoline surfactant, and an amine oxide surfactant.

These surfactants are generally commercially available. The surfactant may be used alone. The surfactant may be used in a combination of two or more kinds thereof.

### Method for Producing Etching Solution

A method for producing the etching solution is not particularly limited. The etching solution can be produced by mixing essential components such as the oxidizing agent, the fluoride, the compound represented by the formula (1), the carboxylic acid as a solvent, and the water with optional components contained as necessary.

### Etching Method

The above-described etching solution can be used for etching the compound represented by Si₁₋ₓGeₓ (x is 0.25 or more and 1 or less). Specifically, the etching solution can be used for etching an object containing the compound represented by Si₁₋ₓGeₓ (x is 0.25 or more and 1 or less). Such an etching method includes an etching step of etching the compound represented by Si₁₋ₓGeₓ by bringing the above-described etching solution into contact with the compound represented by Si₁₋ₓGeₓ.

### Object

In the etching method, the object containing the compound represented by Si₁₋ₓGeₓ (x is 0.25 or more and 1 or less) is an etching treatment target. In the compound represented by Si₁₋ₓGeₓ, x may be 0.25 or more and 1 or less, may be 0.30 or more and 0.80 or less, and may be 0.40 or more and 0.60 or less. The object is not particularly limited as long as the object contains the compound represented by Si₁₋ₓGeₓ. Examples of the object include a substrate having an Si₁₋ₓGeₓ containing layer (a layer containing the compound represented by Si₁₋ₓGeₓ). The above-described substrate is not particularly limited, and examples thereof include various substrates such as a semiconductor wafer, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk. As the substrate, a substrate used for producing a semiconductor device is preferable. The substrate may have various layers and structures as appropriate in addition to the Si₁₋ₓGeₓ containing layer and a base material of the substrate, for example, a metal wiring, a gate structure, a source structure, a drain structure, an insulating layer, a ferromagnetic layer, and a nonmagnetic layer. An uppermost layer of a device surface of the substrate may be the Si₁₋ₓGeₓ containing layer, but the uppermost layer of the device surface of the substrate does not have to be the Si₁₋ₓGeₓ containing layer, and for example, an intermediate layer of the multilayer structure may be the Si₁₋ₓGeₓ containing layer. A size, a thickness, a shape, a layer structure, and the like of the substrate can be appropriately selected according to a purpose without any limitation.

A thickness of the Si₁₋ₓGeₓ containing layer on the substrate is not particularly limited and can be appropriately selected according to the purpose. The thickness of the Si₁₋ₓGeₓ containing layer is, for example, 1 nm or more and 200 nm or less, or 1 nm or more and 20 nm or less.

The object is preferably a substrate including a first SiGe region made of the compound represented by Si₁₋ₓGeₓ and a second SiGe region made of the compound represented by Si_{1-y}Ge_{y} (y is a value of 0 or more and less than x). The substrate including the first SiGe region and the second SiGe region may be a substrate having a stacked body obtained by stacking a layer including the first SiGe region (the Si₁₋ₓGeₓ containing layer) and a layer including the second SiGe region (an Si_{1-y}Ge_{y} containing layer). In the compound represented by Si_{1-y}Ge_{y}, y may be a value of 0 or more and less than x, may be more than 0 and 0.45 or less, and may be 0.10 or more and 0.30 or less. Since the above-described etching solution has excellent etching selectivity towards Si₁₋ₓGeₓ compared to Si_{1-y}Ge_{y}, etching of the first SiGe region (Si₁₋ₓGeₓ) can preferentially proceed on the substrate including the first SiGe region and the second SiGe region.

The etching solution may be used to perform microfabrication on the Si₁₋ₓGeₓ containing layer (for example, to remove at least a part of the Si₁₋ₓGeₓ containing layer) on the substrate as the object, may be used to remove Si₁₋ₓGeₓ containing deposits adhering to the substrate, or may be used to remove impurities such as particles from the object including the Si₁₋ₓGeₓ containing layer on the surface.

The method of forming the Si₁₋ₓGeₓ containing layer or the Si_{1-y}Ge_{y} containing layer (the layer containing the compound represented by Si_{1-y}Ge_{y}) on the substrate is not particularly limited, and a well-known method can be used. Examples of such a method include a sputtering method, a chemical vapor deposition (CVD) method, an epitaxial growth method, and an atomic layer deposition (ALD) method. A raw material of the Si₁₋ₓGeₓ containing layer or the Si_{1-y}Ge_{y} containing layer used for forming the Si₁₋ₓGeₓ containing layer or the Si_{1-y}Ge_{y} containing layer on the substrate is not particularly limited, and can be appropriately selected according to a film forming method.

### Etching Step

In the etching step, the above-described compound represented by Si₁₋ₓGeₓ is etched by bringing the above-described etching solution into contact with the compound represented by Si₁₋ₓGeₓ. A method of bringing the etching solution into contact with the compound represented by Si₁₋ₓGeₓ is not particularly limited, and a well-known etching method can be used. Examples of such a method include, but are not limited to, a spray method, a dipping method, and a puddle method. In the spray method, for example, the above-described etching solution is sprayed onto the object containing the compound represented by Si₁₋ₓGeₓ, and the etching solution comes into contact with the compound represented by Si₁₋ₓGeₓ. If necessary, the above-described etching solution may be sprayed while the substrate is transported or while the substrate is rotated using a spin coater. In the dipping method, the object containing the compound represented by Si₁₋ₓGeₓ is dipped in the above-described etching solution, and the etching solution comes into contact with the compound represented by Si₁₋ₓGeₓ. In the puddle method, the above-described etching solution is placed on the object containing the compound represented by Si₁₋ₓGeₓ, and the etching solution comes into contact with the compound represented by Si₁₋ₓGeₓ. These methods for the etching treatment may be appropriately selected according to the structure or material of the object containing the compound represented by Si₁₋ₓGeₓ. In the case of the spray method or the puddle method, a supply amount of the etching solution to the object may be an amount in which a surface to be processed on the object is sufficiently wet with the etching solution.

A temperature for performing etching is not particularly limited, and may be, for example, a temperature at which the compound represented by Si₁₋ₓGeₓ is dissolved in the etching solution. The temperature for performing etching is a temperature of the etching solution during etching. The etching temperature is, for example, 15° C. or more and 60° C. or less. In any one of the spray method, the dipping method, and the puddle method, the etching rate is increased by increasing the temperature of the etching solution, but a processing temperature can be appropriately selected in consideration of keeping a small change in compositions of the etching solution, the workability, the safety, the cost, and the like.

A time for performing etching may be appropriately selected according to a purpose of the etching treatment, an amount of the compound represented by Si₁₋ₓGeₓ to be removed by etching (for example, a thickness of the Si₁₋ₓGeₓ containing layer and an amount of deposits of Si₁₋ₓGeₓ), and etching process conditions. The time for performing etching (the time of contact with the etching solution) may be, for example, 1 minute or more and 60 minutes or less.

### Method for Manufacturing Semiconductor Device

In the above-described etching solution, the etching selectivity, compared to silicon germanium (Si_{1-y}Ge_{y}), towards Si₁₋ₓGeₓ having a higher concentration of germanium than that of silicon germanium (Si_{1-y}Ge_{y}) is excellent. Therefore, the present invention is particularly suitable for a structure obtained by alternately stacking silicon germanium (Si_{1-y}Ge_{y}) and silicon germanium (Si₁₋ₓGeₓ) having a higher concentration of germanium than that of silicon germanium (Si_{1-y}Ge_{y}) and used for forming a semiconductor device such as a gate-all-around transistor. Specifically, a method for manufacturing a semiconductor device includes an etching step of etching an object containing the compound represented by Si₁₋ₓGeₓ (x is 0.25 or more and 1 or less) by using the above-described etching solution. The object, the etching step, and the like in the method for manufacturing a semiconductor device are the same as the object, the etching step, and the like in the above-described [Etching Method].

The method for manufacturing a semiconductor device may include other steps in addition to the etching step. The other steps are not particularly limited, and examples thereof include a well-known step performed when a semiconductor device is manufactured. Examples of such a step include, but are not limited to, steps of forming a channel, forming a High-K/metal gate, and forming various structures such as a metal wiring, a gate structure, a source structure, a drain structure, an insulating layer, a ferromagnetic layer, and a nonmagnetic layer (layer formation, etching other than the above-described etching step, chemical mechanical polishing, modification, and the like), a resist film formation step, an exposure step, a development step, a heat treatment step, a cleaning step, and an inspection step. The other steps can be appropriately performed before or after the etching step as necessary.

### EXAMPLES

Hereinafter, the present invention will be described in more detail with reference to Examples, but the present invention is not limited to these Examples.

### Examples 1 to 7 and Comparative Examples 1 to 7

### Preparing Etching Solution

The oxidizing agent, the fluoride, the compound represented by the formula (1) or the compound not corresponding to the formula (1) of the kind and mass % shown in Table 1, and the water and the acetic acid (carboxylic acid as a solvent) of mass % shown in Table 1 were mixed to prepare etching solutions of Examples and Comparative Examples. A ratio ((mass of compound represented by formula (1) or compound not corresponding to formula (1))/(mass of acetic acid)) of the mass of the compound represented by the formula (1) or the compound not corresponding to the formula (1) to a mass of the acetic acid is described in a “ratio (formula (1)/acetic acid)” column of Table 1. In Comparative Examples 1, 5, and 6, the compound represented by the formula (1) or the compound not corresponding to the formula (1) was not mixed. In Comparative Example 7, the acetic acid was not mixed. In Table 1, HFSA means hexafluorosilicic acid.

TABLE 1

| | | | | | Compound represented by | | | | |
|---|---|---|---|---|---|---|---|---|---|
| | | | | | formula (1) or compound | | | | Ratio |
| | | | | | not corresponding to | | | Acetic | (formula |
| | Oxidizing agent | | Fluoride | | formula (1) | | Water | acid | (1)/acetic |
| | Type | Mass % | Type | Mass % | Type | Mass % | Mass % | Mass % | acid) |
| Example 1 | Nitric acid | 0.5 | HF | 0.1 | A | 9.7 | 2.1 | 87.6 | 0.11 |
| Example 2 | Nitric acid | 0.5 | HF | 0.1 | B | 9.7 | 2.1 | 87.6 | 0.11 |
| Example 3 | Nitric acid | 0.5 | HF | 0.1 | C | 9.7 | 2.1 | 87.6 | 0.11 |
| Example 4 | Nitric acid | 0.5 | HF | 0.1 | A | 16.5 | 2.1 | 80.8 | 0.20 |
| Example 5 | Nitric acid | 0.5 | HFSA | 1.6 | C | 0.95 | 2.1 | 94.9 | 0.01 |
| Example 6 | Hydrogen | 2.0 | HF | 0.1 | A | 9.2 | 6.4 | 82.4 | 0.11 |
| | peroxide | | | | | | | | |
| Example 7 | Nitric acid | 0.5 | HFSA | 1.6 | A | 9.5 | 2.6 | 85.8 | 0.11 |
| Comparative | Nitric acid | 0.5 | HF | 0.1 | — | — | 2.1 | 97.3 | — |
| Example 1 | | | | | | | | | |
| Comparative | Nitric acid | 0.5 | HF | 0.1 | D | 9.7 | 2.1 | 87.6 | 0.11 |
| Example 2 | | | | | | | | | |
| Comparative | Nitric acid | 0.5 | HF | 0.1 | E | 9.7 | 2.1 | 87.6 | 0.11 |
| Example 3 | | | | | | | | | |
| Comparative | Nitric acid | 0.5 | HF | 0.1 | F | 9.7 | 2.1 | 87.6 | 0.11 |
| Example 4 | | | | | | | | | |
| Comparative | Hydrogen | 2.0 | HF | 0.1 | — | — | 6.4 | 91.6 | — |
| Example 5 | peroxide | | | | | | | | |
| Comparative | Nitric acid | 0.5 | HFSA | 1.6 | — | — | 2.6 | 95.4 | — |
| Example 6 | | | | | | | | | |
| Comparative | Nitric acid | 0.5 | HF | 0.1 | A | 9.7 | 89.7 | 0 | — |
| Example 7 | | | | | | | | | |

The compound represented by the formula (1) and the compound not corresponding to the formula (1) shown in Table 1 are as follows.
A: malonic acid
B: methylmalonic acid
C: acetylacetone
D: oxalic acid
E: succinic acid
F: glutaric acid

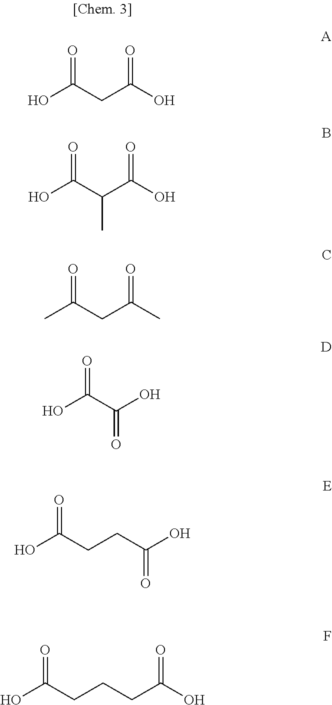

### Etching Treatment (1) of Object

A blanket substrate having an Si_{0.50}Ge_{0.50} layer on a surface thereof was dipped in hydrofluoric acid (HF: water=1:100 (mass ratio)) to remove an oxide film on the surface of the substrate. The substrate was then washed with deionized water (DIW). The substrate after being washed was dried by a nitrogen stream. The substrate after being dried was dipped in the etching solution at 25° C. for 1 minute for etching. After being dipped, the substrate was washed with deionized water (DIW). The substrate after being washed was dried by the nitrogen stream.

Film thicknesses of the Si_{0.50}Ge_{0.50} layer on the surface of the substrate before being dipped in hydrofluoric acid and the substrate after being washed and dried after being dipped in the etching solution were measured using X-ray fluorescence analysis (XRF), and an etching rate ((difference [nm] in film thicknesses)/(dipping time [min] in etching solution)) of Si_{0.50}Ge_{0.50} was calculated from a difference in the film thicknesses and a dipping time in the etching solution. Results are shown in Table 2.

### Etching Treatment (2) of Object

The same operation as <Etching Treatment (1) of Object> was performed except that a blanket substrate having an Si_{0.80}Ge_{0.20} layer on a surface was used instead of the blanket substrate having the Si_{0.50}Ge_{0.50} layer on the surface. Film thicknesses of the Si_{0.80}Ge_{0.20} layer on the surface of the substrate before being dipped in hydrofluoric acid and the substrate after being washed and dried after being dipped in the etching solution were measured using X-ray fluorescence analysis (XRF), and an etching rate ((difference [nm] in film thicknesses)/(dipping time [min] in etching solution)) of Si_{0.50}Ge_{0.20} was calculated from a difference in the film thicknesses and a dipping time in the etching solution. Results are shown in Table 2. Table 2 shows an etching selection ratio ((etching rate of Si_{0.50}Ge_{0.50})/(etching rate of Si_{0.80}Ge_{0.20})) calculated from the etching rate of Si_{0.50}Ge_{0.50} and an etching rate of Si_{0.80}Ge_{0.20}.

The Si_{0.50}Ge_{0.20} layer on the surface of the substrate after being washed and dried after being dipped in the etching solution was observed with a scanning electron microscope (SEM), and flatness (surface roughness) was evaluated according to the following criteria. The Si_{0.80}Ge_{0.20} layer on the surface of the substrate before being dipped in the etching solution was flat, and no surface roughness was observed.
A: no decrease in flatness (surface roughness) is observed.
B: a slight decrease in flatness (surface roughness) is observed.
C: a decrease in flatness (surface roughness) is observed on the entire surface, but a degree of decrease in flatness (surface roughness) is small.
D: a decrease in flatness (surface roughness) is observed on the entire surface, and the degree of decrease in flatness (surface roughness) is large.

From the results shown in Table 2, it was confirmed that compared with the etching solutions of Comparative Examples 1 to 7, the etching solutions of Examples 1 to 7 had a higher Si_{0.50}Ge_{0.50} etching selection ratio, and had excellent etching selectivity, compared to silicon germanium (Si_{1-y}Ge_{y}), towards the compound represented by Si₁₋ₓGeₓ (x is 0.25 or more and 1 or less) having a higher concentration of germanium than that of silicon germanium (Si_{1-y}Ge_{y}). It was confirmed that compared with the etching solutions of Comparative Examples 1 to 7, the etching solutions of Examples 1 to 7 can suppress the decrease in the flatness of Si_{1-y}Ge_{y}.

TABLE 2

| | | | Etching | |
|---|---|---|---|---|
| | Etching rate | | selection ratio | |
| | [nm/min] | | Si_{0.50}Ge_{0.50}/ | |
| | Si_{0.50}Ge_{0.50} | Si_{0.80}Ge_{0.20} | Si_{0.80}Ge_{0.20} | Flatness |
| Example 1 | 13.0 | 0.07 | 181.3 | A |
| Example 2 | 15.1 | 0.12 | 121.0 | A |
| Example 3 | 9.2 | 0.04 | 225.4 | A |
| Example 4 | 16.9 | 0.03 | 506.2 | A |
| Example 5 | 9.2 | 0.04 | 225.4 | A |
| Example 6 | 13.6 | 0.09 | 146.7 | A |
| Example 7 | 86.6 | 0.05 | 1842.6 | A |
| Comparative | 5.8 | 0.20 | 28.5 | C |
| Example 1 | | | | |
| Comparative | 4.3 | 0.40 | 10.2 | D |
| Example 2 | | | | |
| Comparative | 8.4 | 0.26 | 32.2 | C |
| Example 3 | | | | |
| Comparative | 8.5 | 0.44 | 19.3 | D |
| Example 4 | | | | |
| Comparative | 11.0 | 0.12 | 94.1 | B |
| Example 5 | | | | |
| Comparative | 18.6 | 0.22 | 84.3 | B |
| Example 6 | | | | |
| Comparative | 1.09 | 0.05 | 23.5 | C |
| Example 7 | | | | |

### Etching Treatment (3) of Object

In Example 1 or Comparative Example 1, the same operation as <Etching Treatment (1) of Object> was performed except that an SOI substrate was used instead of the blanket substrate having the Si_{0.50}Ge_{0.50} layer on the surface. Film thicknesses of an Si layer on the surface of the substrate before being dipped in the etching solution and after being washed and dried after being dipped in hydrofluoric acid and the substrate after being washed and dried after being dipped in the etching solution were measured using spectroscopic ellipsometry, and an etching rate ((difference [nm] in film thicknesses)/(dipping time [min] in etching solution)) of Si was calculated from a difference in the film thicknesses and a dipping time in the etching solution. Results are shown in Table 3.

The Si layer on the surface of the substrate after being washed and dried after being dipped in the etching solution was observed with a scanning electron microscope (SEM), and flatness (surface roughness) was evaluated according to the following criteria. The Si layer on the surface of the substrate before being dipped in the etching solution was flat, and no surface roughness was observed.

A: no decrease in flatness (surface roughness) is observed.

B: a slight decrease in flatness (surface roughness) is observed.

C: a decrease in flatness (surface roughness) is observed on the entire surface, but a degree of decrease in flatness (surface roughness) is small.

D: a decrease in flatness (surface roughness) is observed on the entire surface, and the degree of decrease in flatness (surface roughness) is large.

As shown in Table 3, in each of Example 1 and Comparative Example 1, the etching rate of Si was extremely low, and Si was substantially not etched. On the other hand, the etching rate of Si_{0.50}Ge_{0.50} in Example 1 is higher than that in Comparative Example 1. Therefore, it was confirmed that compared with the etching solution of Comparative Example 1, the etching solution of Example 1 had a higher Si_{0.50}Ge_{0.50} etching selection ratio, and had excellent etching selectivity towards the compound represented by Si₁₋ₓGeₓ (x is 0.25 or more and 1 or less) compared to Si. It was confirmed that compared with the etching solution of Comparative Example 1, the etching solution of Example 1 can suppress the decrease in the flatness of Si.

TABLE 3

| | |
|---|---|
| Etching rate | |
| [nm/min] | Flatness |

| | Si_{0.50}Ge_{0.50} | Si | of Si |
|---|---|---|---|
| Example 1 | 13.0 | Less than 0.01 | A |
| Comparative | 5.8 | Less than 0.01 | B |
| Example 1 | | | |

What is claimed is:

1. An etching solution, comprising an oxidizing agent, a fluoride, a compound represented by the following formula (1), a carboxylic acid as a solvent, and water, 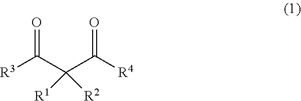
wherein R¹ and R² each independently represents a hydrogen atom, a halogen atom, an alkyl group, a fluoroalkyl group, or an alkoxy group, and R³ and R⁴ each independently represents a halogen atom, a hydroxy group, an alkyl group, a fluoroalkyl group, or an alkoxy group.

2. The etching solution according to claim 1, wherein a ratio ((mass of compound represented by formula (1))/(mass of carboxylic acid as solvent)) of a mass of the compound represented by the formula (1) to a mass of the carboxylic acid as a solvent is 0.10 or more and 0.25 or less.

3. The etching solution according to claim 1, wherein a mass of the compound represented by the formula (1) is 8.5 mass % or more and 20% or less with respect to a mass of the etching solution, and a mass of the carboxylic acid as a solvent is 70 mass % or more and 98 mass % or less with respect to the mass of the etching solution.

4. The etching solution according to claim 1, wherein the oxidizing agent comprises at least one of nitric acid or hydrogen peroxide.

5. The etching solution according to claim 1, wherein the fluoride comprises at least one of hexafluorosilicic acid or hydrogen fluoride.

6. The etching solution according to claim 1, wherein the etching solution etches a compound represented by Si₁₋ₓGeₓ, wherein x is 0.25 or more and 1 or less.

7. An etching method for etching an object comprising a compound represented by Si₁₋ₓGeₓ, wherein x is 0.25 or more and 1 or less, the etching method comprising etching the compound represented by Si₁₋ₓGeₓ by bringing the etching solution according to claim 1 into contact with the compound represented by Si₁₋ₓGeₓ.

8. The etching method according to claim 7, wherein the object is a substrate comprising a first SiGe region made of the compound represented by Si₁₋ₓGeₓ and a second SiGe region made of a compound represented by Si_{1-y}Ge_{y}, wherein y is 0 or more and less than x.

9. A method for manufacturing a semiconductor device, comprising etching an object containing a compound represented by Si₁₋ₓGeₓ, wherein x is 0.25 or more and 1 or less, using the etching solution according to claim 1.

10. The method for manufacturing a semiconductor device according to claim 9, wherein the semiconductor device is a gate-all-around transistor.
